(19) United States
(12) Patent Application Publication
(10) Pub. No.: US 2011/0103621 A1
(43) Pub. Date: May 5, 2011

(54) THERMO-ACOUSTIC LOUDSPEAKER

(75) Inventor: Josef LUTZ, Rohrau (AT)

(73) Assignee: NXP B.V., Eindhoven (NL)

(21) Appl. No.: 12/914,833

(22) Filed: Oct. 28, 2010

(30) Foreign Application Priority Data
Nov. 3, 2009 (EP) 09174810.3

(51) Int. Cl. H04R 1/00; G03F 7/20

(52) U.S. Cl. 381/164; 430/315

(57) ABSTRACT

A thermo-acoustic loudspeaker has a heating sheet and a plurality of support bars supporting the heating sheet away from a substrate. The heating sheet has at least one opening adjacent to each cavity. During manufacture, the opening or openings are used to etch away the material of the layer under the heating sheet. The layer under the heating sheet may be a sacrificial layer for example of photoresist or silicon dioxide.

This application claims the priority under 35 U.S.C. §119 of European patent application no. 09174810.3, filed on Nov. 3, 2009 the contents of which are incorporated by reference herein.

### FIELD OF THE INVENTION

The invention relates to a thermo-acoustic loudspeaker and method of making it.

### BACKGROUND OF THE INVENTION

In a thermo-acoustic device, a heater warms air which leads to the expansion of the air and hence a sound wave. The heating may take place using for example a heating foil on the top of a substrate driven by an electrical power supply. In order to achieve relatively high frequencies, the heat capacity of the heating foil must be very small and the heat must be able to be transferred to the air very quickly.

Such devices have proven relatively efficient especially in the ultrasound frequency range up to 100 kHz. At lower frequencies below 20 kHz, i.e. in the audible sound range, the technique is less efficient. A problem can be heat loss through the electrical contacts to the heating foil as well as the heat loss from the foil to a substrate material on which the foil is mounted.

Accordingly, it has been proposed to mount the electrical heating layer on porous silicon, H. Shinoda et al, “Thermally induced ultrasonic emission from porous silicon”, Nature, volume 400, pages 853 to 854. This approach has two advantages, firstly porous silicon has a very low thermal conductivity, and secondly the loudspeaker can be manufactured using well-known semiconductor process technology. However, it has still not been possible to achieve an efficient sound source in the audible sound range below 20 kHz.

### SUMMARY OF THE INVENTION

According to an aspect of the invention there is provided a loudspeaker according to claim 1.

The loudspeaker according to claim 1 achieves a low thermal conductivity to the substrate since the heating foil or sheet is not in contact with the substrate except over a limited area. Moreover, the loudspeaker is relatively straightforward to manufacture.

The support bars may be porous silicon. This minimizes heat transfer.

Alternatively, silicon dioxide or even the silicon of the substrate may be used as the support bars in alternative processes.

In another aspect, there is provided a method of manufacturing a loudspeaker according to claim 7.

### BRIEF DESCRIPTION OF THE DRAWINGS

Embodiments of the invention will now be described, purely by way of example, with reference to the accompanying drawings, in which:

FIGS. 1 and 2 show steps of a method in accordance with a first embodiment of the invention in side view;

FIG. 3 shows the resulting loudspeaker in accordance with the embodiment of FIG. 1 in side view

FIGS. 4 to 7 show possible arrangements of electrical connections in top view in the embodiment shown in FIGS. 1 to 7; and

FIGS. 8 and 9 show steps in a method according to a second embodiment of the invention.

Like or similar components are given the same reference numbers in the different figures, and the description relating is not necessarily repeated.

### DETAILED DESCRIPTION OF EMBODIMENTS

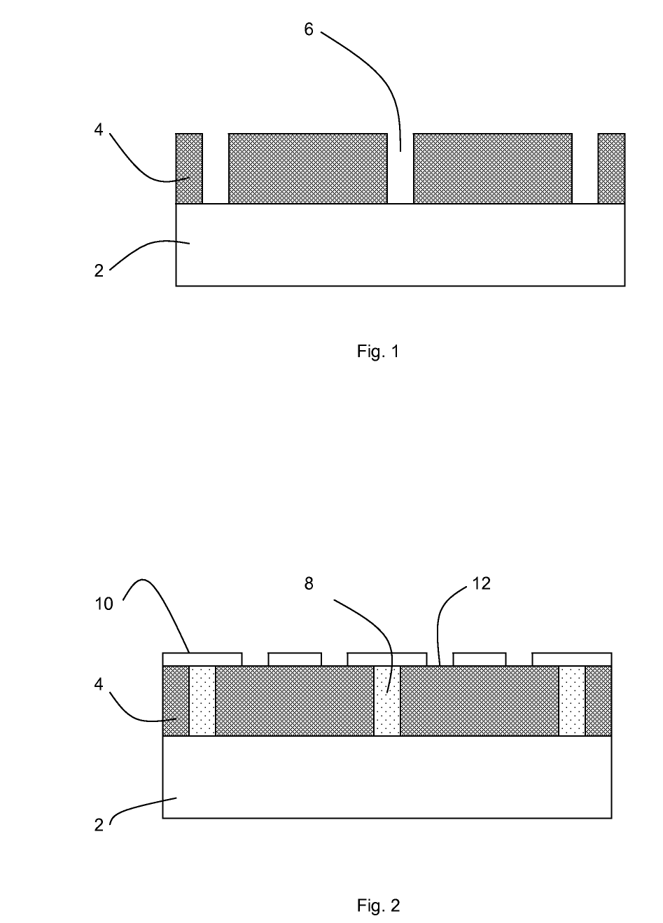

According to FIG. 1, a silicon substrate 2 is provided, and photoresist 4 deposited on top. The photoresist is then patterned to define gaps 6 between remaining photoresist in a first pattern. As will be apparent from the description below, the remaining photoresist is at locations where one or more cavities or gaps are formed in the final device. The patterning process can take place in a number of ways, as known to those skilled in the art, and any suitable photoresist, either positive or negative, may be used.

Then, as illustrated in FIG. 2, porous silicon is then formed in the gaps by methods known to those skilled in the art to form support structures 8.

A layer of heating sheet, in the particular example a thin layer of metal, is deposited on the photoresist 4 and gaps 6 to form a flat sheet 10. Photoresist is then deposited and patterned to form a second pattern, and an etch carried out to etch away openings 12 in the flat sheet, which act as venting holes.

The openings 12 within heating sheet 10 optimise the acoustical performance. The area of the openings is of the order of 20-35% of the total area. The diameter of the openings is selected depending on the distance between sheet 10 and substrate 2. The diameter in the order of between 1 and 4 times the distance between the heating layer and the substrate.

The thickness of the heating sheet 10 is determined by the need for low heat capacity but with the necessary mechanical robustness.

The resistance of the heating sheet may be of order 10Ω, typically 2 ohms to 50Ω. For mobile applications the total resistance should be in the order of 10Ω.

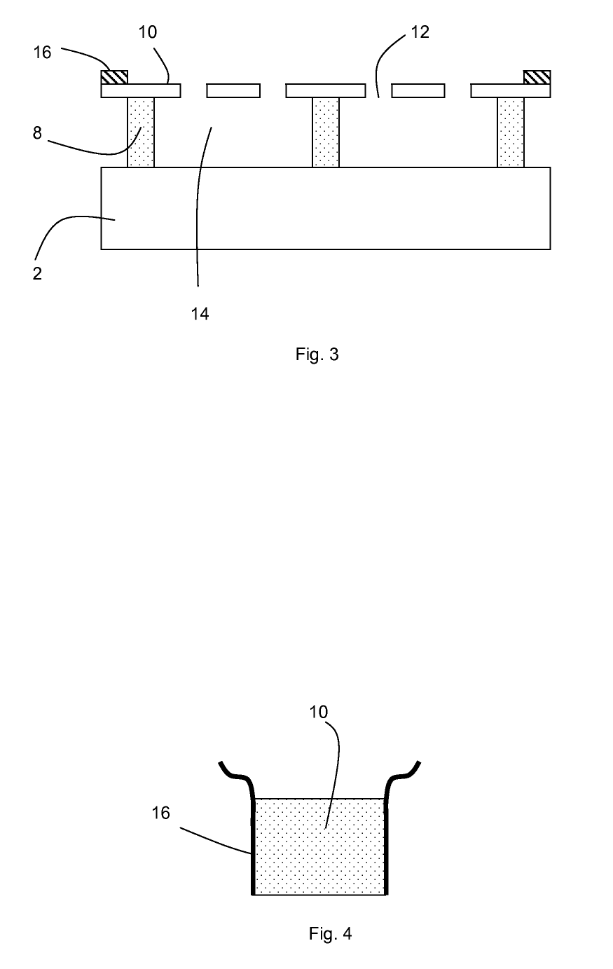

Then, the photoresist 4 is removed by dissolving the photoresist 4 in solvent, which passes through the openings 12, leaving cavities 14. Each cavity 14 is adjacent to at least one opening 12. Contacts 16 are then formed, leaving the finished product as illustrated in FIG. 3.

The electrical connection to the heating layer should be optimised for a reasonable low electrical contact resistance (low losses) and a high resistance for heat transfer, e.g. “bottle neck structures” in the connection line.

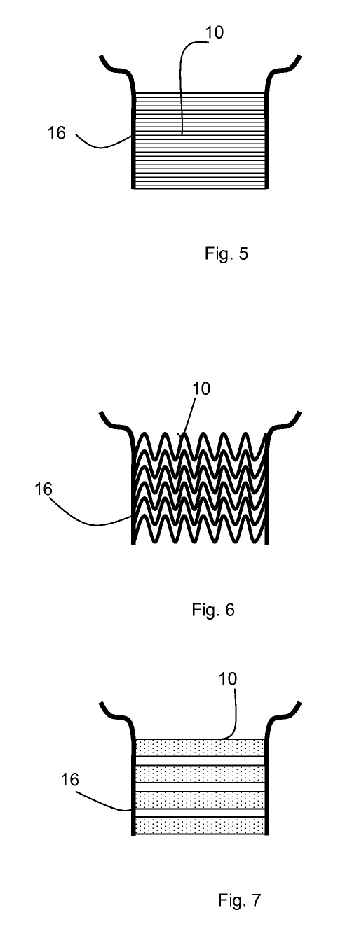

This can be done in several ways. Some possibilities are illustrated in FIGS. 4 to 7 which show a top view of the electrical arrangements.

FIG. 4 shows an arrangement having a rectangular area of heating sheet 10 with small holes shown as dots between the contacts 16 on opposite sides of the rectangular shape.

In FIG. 5, there is also a rectangular area of heating sheet 10 but these take the form of thin straight wires 50 between the contacts 16 at both sides. This is generally effective if the width of the wires is smaller than double the undercut. The gaps between the wires 50 act as the openings 12 and no further openings are necessary.

An arrangement like FIG. 5 with wires 50 and the gaps between the wires forming the openings 12 is shown in FIG. 6. In this case, the wires 50 meander to increase the resistance.

In FIG. 7, a similar arrangement is provided where the wires 50 are wider with the openings 12 again between the wires 50 with the openings of larger width to remove the sacrificial layer between heating layer and substrate.

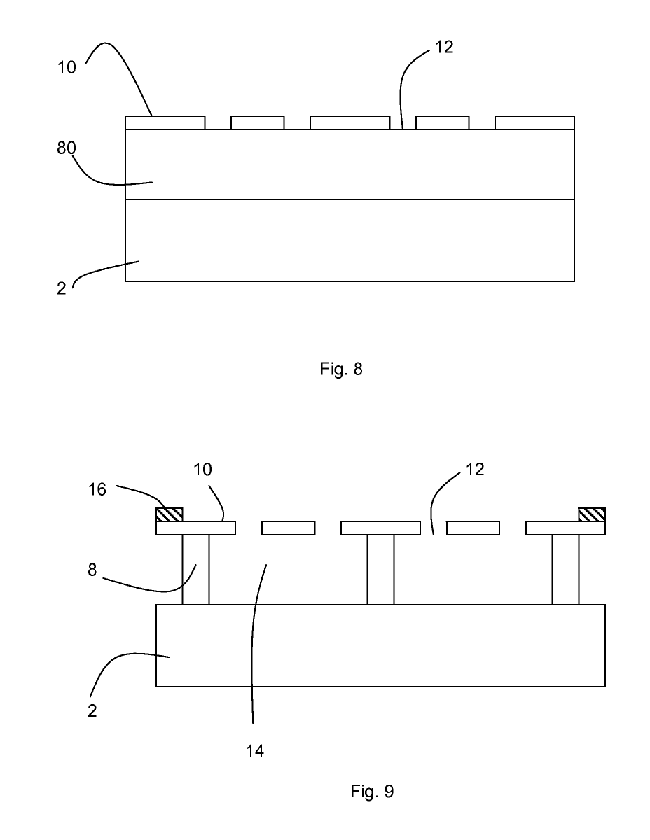

Instead of the manufacture using the deposition of photoresist in an alternative embodiment illustrated in FIGS. 8 and 9 a layer of silicon oxide 80 is deposited on the substrate 2

Afterwards, without any step between, the heating layer 10 is deposited over the full surface. The next step is the structuring of this heating layer by defining openings 12 and the area of heating layer using standard silicon lithography and etching steps to arrive at the arrangement shown in FIG. 8.

In this embodiment, the openings 12 allow the etching of the layer 80 below, in addition the need for suitable acoustic behaviour as discussed above.

The, the silicon dioxide layer 80 is etched, for example using a wet etch or a HF vapour etch, or indeed any other suitable. In this embodiment, support structures 8 are produced automatically if the holes in the heating layer have larger distances at defined positions. The horizontal etching will be limited and the remaining silicon dioxide 80 remains to act as the support structures 8 with cavities 14.

In a variation on this method, instead of porous silicon as in the first embodiment or silicon oxide 80 as in the second embodiment conventional silicon may be used to form supports 8. In this case, the conventional silicon can be an epilayer or indeed simply part of the substrate 2 to reduce cost and use more standard process steps.

Thus, although the first and second embodiments of the invention use a separate sacrificial layer 4,80 as a material to form the cavities, this alternative embodiment simply uses the material of the substrate 2 itself as the material to be etched to form the cavities 14. This material is referred to elsewhere as the “first material”. Where the substrate is used, the substrate may be glass, for example.

It should be noted that alternative approaches exist.

The substrate can be any suitable substrate such as a silicon wafer, or glass, depending on the available material, the processes available and not least cost.

The heating sheet can be of metal, doped silicon, a combination, or indeed any other material of suitable resistance.

The number and dimensions of support structures depend on the necessary mechanical stability and the shape of the heating layer

The heating sheet may be as thin as possible for low heat capacity but thick enough for necessary mechanical stability and resisitivity (order of magnitude: depending on material˜μm). The material may be doped silicon or metal or a combination or any other suitable heating material. A metal layer, for example aluminium, may be provided on the top in which case there may be no need for separate contacts 16. In this case, the heating sheet can be directly contacted by standard bonding processes.

In the event that a separate sacrificial layer is used as the first material, for example of silicon oxide or photoresist, the sacrificial layer and/or the substrate should be an electrical isolator to avoid a short cut or parallel current path. The sacrificial layer should be for most applications larger than 2 μm. Ultimately, the thickness will be limited by the chosen production processes, for example with regard to the maximum thickness of deposited layers, etching selectivity or time, and other considerations.

The substrate may be silicon, silicon oxide (glass) or indeed any known substrate depending on cost, application, and processes. For higher efficiency in certain applications it may be advantageous to introduce ventilation holes into the substrate, similar to the openings in the heating layer. The thickness of the substrate may vary according to the necessary mechanical stability and handling conditions, the thickness may be for example greater than 50 μm.

The cavity need not be a closed cavity in any sense and the cavity may in particular be open at the sides, top, or indeed elsewhere.

The finished devices illustrated above in different embodiments have has the sheet 10 supported only on structures 8 taking up less than half of the total area, in typical arrangements 25% or less.

The efficiency of the device is substantially improved due to the drastically reduced heat transfer via the support structures 8 into substrate. A number of effects are involved in this. Firstly, the thin columns result in the reduction of the heat loss into the substrate, and corresponding increase in local heating of a fluid such as air or liquid in which the device is placed. In some embodiments these advantages are increased by using a low thermal conductivity material, for example porous silicon as used in the first embodiment described.

Both sides of the heating sheet 10 are used for the production of sound.

These advantages in the finished product are achieved in a device that is relatively easy to manufacture. There is only one patterning step and two deposition steps—indeed, in some cases where a separate first material sacrificial layer is not deposited on the substrate but the substrate is used as the first material only one deposition step is enough.

Moreover, the finished device can be a very flat loudspeaker that does not require any rear cavity behind to operate. Also, the device can be formed in almost any shape required which makes the device easy to integrate into other equipment.

1. A thermo-acoustic loudspeaker comprising:
a substrate;
a heating sheet; and
a plurality of support bars supporting the heating sheet away from the substrate, the support bars at least partially defining at least one cavity between the support bars;
wherein the heating sheet extends between opposed contacts over the at least one cavity; and
wherein the heating sheet has at least one opening adjacent to each cavity;

2. A thermo-acoustic loudspeaker according to claim 1, wherein the support bars include porous silicon.

3. A thermo-acoustic loudspeaker according to claim 1 wherein the support bars include silicon dioxide.

4. A thermo-acoustic loudspeaker according to claim 1 wherein in the plane of the substrate an area ratio of support bars to a total area of support bars and cavities is not more than 25%.

5. A thermo-acoustic loudspeaker according to claim 1 wherein the heating sheet has a resistance between 2Ω and 50Ω and a thickness of at most 10 μm.

6. A thermo-acoustic loudspeaker according to claim 1 wherein the heating sheet includes a plurality of one of wires and sheets extending between opposed contacts over the at least one cavity.

7. A method of manufacturing a thermo-acoustic loudspeaker, comprising:
forming a heating sheet over a first material;
patterning the heating sheet to form a pattern with openings in the heating sheet; and
removing the first material through the openings to form cavities between support structures; and
wherein the heating sheet extends between opposed contacts over the cavities.

8. A method according to claim 7, further comprising:
depositing a sacrificial layer as the first material on a substrate before forming the heating sheet;

9. A method according to claim 8 wherein the sacrificial layer is photoresist, and removing the photoresist includes dissolving the photoresist in a solvent, the solvent passing through the openings in the heating sheet to dissolve the photoresist to form the cavities.

10. A method according to claim 9 further comprising:
patterning the photoresist after deposition to define gaps, and
depositing material to form the support structures in the gaps.

11. A method according to claim 8, wherein the sacrificial layer includes silicon dioxide.

12. A method according to claim 8, wherein the sacrificial layer includes porous silicon.

13. A method according to claim 7 wherein the first material is a substrate.
